(19) United States
(12) Patent Application Publication
(10) Pub. No.: US 2009/0086432 A1
(43) Pub. Date: Apr. 2, 2009

(54) DOCKING STATION WITH CLOSED LOOP AIRLFOW PATH FOR FACILITATING COOLING OF AN ELECTRONICS RACK

(75) Inventors: Levi A. CAMPBELL, Poughkeepsie, NY (US); Richard C. CHU, Hopewell Junction, NY (US); Michael J. ELLSWORTH, Jr., Lagrangeville, NY (US); Madhusudan K. IYENGAR, Woodstock, NY (US); Robert E. SIMONS, Pouhkeepsie, NY (US)

Correspondence Address: HESLIN ROTHENBERG FARLEY & MESITI P.C., 5 COLUMBIA CIRCLE, ALBANY, NY, 12203, US

(73) Assignee: INTERNATIONAL BUSINESS MACHINES CORPORATION, Armonk, NY (US)

(21) Appl. No.: 11/862,328

(22) Filed: Sep. 27, 2007

(51) Int. Cl. H05K 7/20; F28D 15/00

(52) U.S. Cl. 361/696; 165/104.33; 165/104.21

(57) ABSTRACT

A docking station is provided for cooling an electronics rack of a data center. The docking station includes an enclosure having at least one wall, a cover coupled to the at least one wall, and a central opening sized to receive the electronics rack therein through an access opening in the wall. The enclosure is separate and freestanding from the electronics rack, and when the electronics rack is operatively positioned within the central opening, the enclosure surrounds the electronics rack and facilitates establishing a closed loop airflow path passing through air inlet and outlet sides of the rack and through an air return pathway of the enclosure. The docking station further includes an air-to-liquid heat exchange assembly disposed within the air return pathway of the enclosure for cooling circulating air passing through the closed loop airflow path.

### CROSS-REFERENCE TO RELATED APPLICATIONS

This application contains subject matter which is related to the subject matter of the following applications, each of which is assigned to the same assignee as this application and each of which is hereby incorporated herein by reference in its entirety:

“Docking Station with Hybrid Air and Liquid Cooling of an Electronics Rack”, by Campbell et al., U.S. patent application Ser. No. ______, co-filed herewith (Attorney Docket No.: POU920070180US1);

“Method of Assembling a Cooling System for a Multi-Component Electronics System”, by Campbell et al., U.S. patent application Ser. No. 11/539,907, filed Oct. 10, 2006; and

“Liquid-Based Cooling System for Cooling a Multi-Component Electronics System”, by Campbell et al., U.S. patent application Ser. No. 11/539,910, filed Oct. 10, 2006.

### TECHNICAL FIELD

The present invention relates in general to systems and methods for cooling rack-mounted assemblages of individual electronics units, such as rack-mounted computer server units.

### BACKGROUND OF THE INVENTION

The power dissipation of integrated circuit chips, and the modules containing the chips, continues to increase in order to achieve increases in processor performance. This trend poses a cooling challenge at both the module and system level. Increased airflow rates are needed to effectively cool high power modules and to limit the temperature of the air that is exhausted into the computer center.

In many large server applications, processors along with their associated electronics (e.g., memory, disk drives, power supplies, etc.) are packaged in removable drawer configurations stacked within a rack or frame. In other cases, the electronics may be in fixed locations within the rack or frame. Typically, the components are cooled by air moving in parallel airflow paths, usually front-to-back, impelled by one or more air moving devices (e.g., fans or blowers). In some cases it may be possible to handle increased power dissipation within a single drawer by providing greater airflow, through the use of a more powerful air moving device or by increasing the rotational speed (i.e., RPMs) of an existing air moving device. However, this approach is becoming problematic at the rack level in the context of a computer installation (i.e., data center).

The sensible heat load carried by the air exiting the rack is stressing the ability of the room air-conditioning to effectively handle the load. This is especially true for large installations with “server farms” or large banks of electronics racks close together. In such installations not only will the room air-conditioning be challenged, but the situation may also result in recirculation problems with some fraction of the “hot” air exiting one rack unit being drawn into the air inlet of the same rack or a nearby rack. This recirculating flow is often extremely complex in nature, and can lead to significantly higher rack inlet temperatures than expected. This increase in cooling air temperature may result in components exceeding their allowable operating temperature and in a reduction in long term reliability of the components.

In addition, with the large number of electronics racks in many data center installations, the acoustic noise generated by both the fans in the electronics racks circulating air through the racks, and the fans of the computer room air-conditioning units required to cool the data center are rising to unacceptably high levels.

### SUMMARY OF THE INVENTION

The shortcomings of the prior art are overcome and additional advantages are provided through a docking station for facilitating cooling of an electronics rack. The docking station includes an enclosure having at least one wall, a cover coupled to the at least one wall, and a central opening sized to receive an electronics rack therein through an access opening in the at least one wall. The enclosure is separate and freestanding from the electronics rack, and the rack includes at least one electronics drawer, and an air inlet side and an air outlet side. The air inlet and air outlet sides of the electronics rack respectively enable ingress and egress of air. When the electronics rack is operatively positioned within the central opening of the enclosure, the enclosure surrounds the electronics rack and facilitates establishing a closed loop airflow path passing through the air inlet and air outlet sides of the electronics rack and through at least one air return path of the enclosure. The docking station further includes at least one air-to-liquid heat exchange assembly disposed within the air return path of the enclosure for cooling circulating air passing through the closed loop air flow path.

In a further aspect, a data center is provided which includes at least one electronics rack and at least one docking station. Each electronics rack includes an air inlet side and an air outlet side. The air inlet and air outlet sides respectively enable ingress and egress of air through the electronics rack. Each docking station includes an enclosure and at least one air-to-liquid heat exchange assembly. The enclosure includes at least one wall, a cover coupled to the at least one wall, and a central opening sized to receive a respective electronics rack therein through an access opening in the at least one wall. The enclosure is separate and freestanding from the electronics rack. When the electronics rack is operatively positioned within the central opening of the enclosure, the enclosure surrounds the electronics rack and facilitates establishing a closed loop airflow path therein passing through the air inlet and air outlet sides of the electronics rack and through at least one air return pathway of the enclosure. The at least one air-to-liquid heat exchange assembly is disposed within the at least one air return pathway of the enclosure for cooling air circulating through the closed loop airflow path.

In a further aspect, a method of cooling an electronics rack is provided. The method includes: providing a docking station for cooling an electronics rack, the docking station comprising: an enclosure comprising at least one wall, a cover coupled to the at least one wall, and a central opening sized to receive the electronics rack therein through an access opening in the at least one wall. The enclosure is separate and freestanding from the electronics rack, and the electronics rack comprising an air inlet side and an air outlet side. The air inlet and air outlet sides respectively enable ingress or egress of air. The docking station further includes at least one air-to-liquid heat exchange assembly disposed within at least one air return pathway of the enclosure for cooling air passing therethrough. Additionally, the method comprises: disposing the electronics rack within the central opening and sealing the electronics rack within the enclosure; establishing airflow through the electronics rack employing at least one air moving device, wherein the establishing results in a closed loop airflow pathway being established within the enclosure passing through the air inlet and air outlet sides of the electronics rack and the at least one air return pathway of the enclosure; and employing the at least one air-to-liquid heat exchange assembly to cool air circulating within the enclosure through the closed loop airflow path.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1A depicts one embodiment of a conventional raised floor layout of an air cooled data center;

FIG. 1B depicts one embodiment of a conventional non-raised floor layout of an air cooled data center, wherein overhead air ducts and diffusers are employed in distributing cooled airflow to the electronics racks;

FIG. 2 depicts one problem addressed by the present invention, showing re-circulation airflow patterns in one implementation of a raised floor layout of an air cooled data center;

FIG. 3A is a cross-sectional plan view of one embodiment of electronics rack using attached facility chilled liquid-to-air heat exchangers to enhance cooling of air passing through the electronics rack;

FIG. 3B is a cross-sectional plan view of another embodiment of an electronics rack using an attached facility chilled liquid-to-air heat exchanger to enhance cooling of air passing though the electronics rack;

FIG. 4A is a top plan view of one embodiment of a data center docking station receiving an electronics rack to be cooled, in accordance with an aspect of the present invention;

FIG. 4B is a top plan view of the docking station of FIG. 4A, showing the electronics rack disposed in operative position therein and a closed loop airflow path established within the docking station, in accordance with an aspect of the present invention;

FIG. 5A is a top plan view of an alternate embodiment of a docking station receiving an electronics rack to be cooled (and shown with the top cover removed), in accordance with an aspect of the present invention;

FIG. 5B is a top plan view of the docking station of FIG. 5A shown with the electronics rack in operative position therein and illustrating a bifurcated closed loop airflow path (and shown with the top cover removed), in accordance with an aspect of the present invention;

FIG. 6A is a top plan view of an alternate embodiment of a docking station receiving an electronics rack to be cooled, in accordance with an aspect of the present invention;

FIG. 6B is a top plan view of the docking station of FIG. 6A shown with the electronics rack in operative position therein and illustrating a bifurcated closed loop airflow path (and shown with the top cover removed), in accordance with an aspect of the present invention;

FIG. 7A is an exploded isometric view of an alternate embodiment of a docking station comprising a central structure and two side structures, in accordance with an aspect of the present invention;

FIG. 7B is an isometric view of the assembled docking station of FIG. 7A, in accordance with an aspect of the present invention;

FIG. 8A depicts one embodiment of a raised floor data center employing the docking station of FIGS. 7A & 7B with the front access door opened to receive the electronics rack to be cooled, in accordance with an aspect of the present invention;

FIG. 8B illustrates the data center and docking station of FIG. 8A, shown with the electronics rack being moved into position within the docking station, in accordance with an aspect of the present invention;

FIG. 8C depicts the data center and docking station of FIGS. 8A & 8B, illustrating the electronics rack disposed in operative position within the central opening of the docking station, in accordance with an aspect of the present invention;

FIG. 9A is a top plan view of one embodiment of a data center employing multiple rows of docking stations with electronics racks illustrated in operative position therein and multiple coolant distribution units providing liquid coolant to the air-to-liquid heat exchange assemblies within the docking stations, in accordance with an aspect of the present invention; and

FIG. 9B is a side elevational view of the data center embodiment of FIG. 9A, in accordance with an aspect of the present invention.

### DETAILED DESCRIPTION OF THE INVENTION

As used herein, the terms “electronics rack”, “rack-mounted electronic equipment”, and “rack unit” are used interchangeably, and unless otherwise specified include any housing, frame, rack, compartment, blade server system, etc., having one or more heat generating components of a computer system or electronics system, and may be, for example, a stand alone computer processor having high, mid or low end processing capability. In one embodiment, an electronics rack may comprise multiple electronics drawers each having one or more heat generating components disposed therein requiring cooling. Further, as used herein, “air-to-liquid heat exchange assembly” means any heat exchange mechanism characterized as described herein through which liquid coolant can circulate; and includes, one or more discrete air-to-liquid heat exchangers coupled either in series or in parallel. An air-to-liquid heat exchanger may comprise, for example, one or more coolant flow paths, formed of thermally conductive tubing (such as copper or other tubing) in thermal or mechanical contact with a plurality of air-cooled cooling fins. Size, configuration and construction of the air-to-liquid heat exchange assembly and/or air-to-liquid heat exchanger thereof can vary without departing from the scope of the invention disclosed herein. Further, “data center” refers to a computer installation containing one or more electronics racks to be cooled. As a specific example, a data center may include one or more rows of rack-mounted computing units, such as server units.

One example of facility coolant and system coolant is water. However, the concepts disclosed herein are readily adapted to use with other types of coolant on the facility side and/or on the system side. For example, one or more of the coolants may comprise a brine, a fluorocarbon liquid, a liquid metal, or other similar coolant, or refrigerant, while still maintaining the advantages and unique features of the present invention.

Reference is made below to the drawings, which are not drawn to scale for reasons of understanding, wherein the same reference numbers used throughout different figures designate the same or similar components.

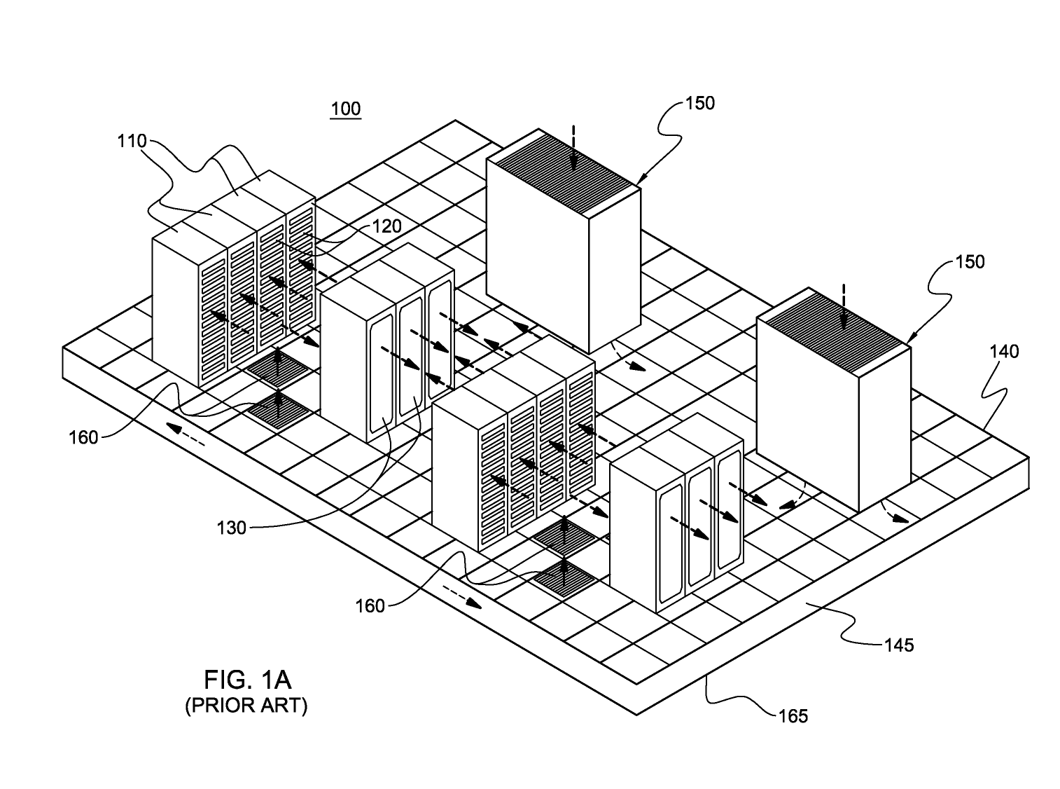

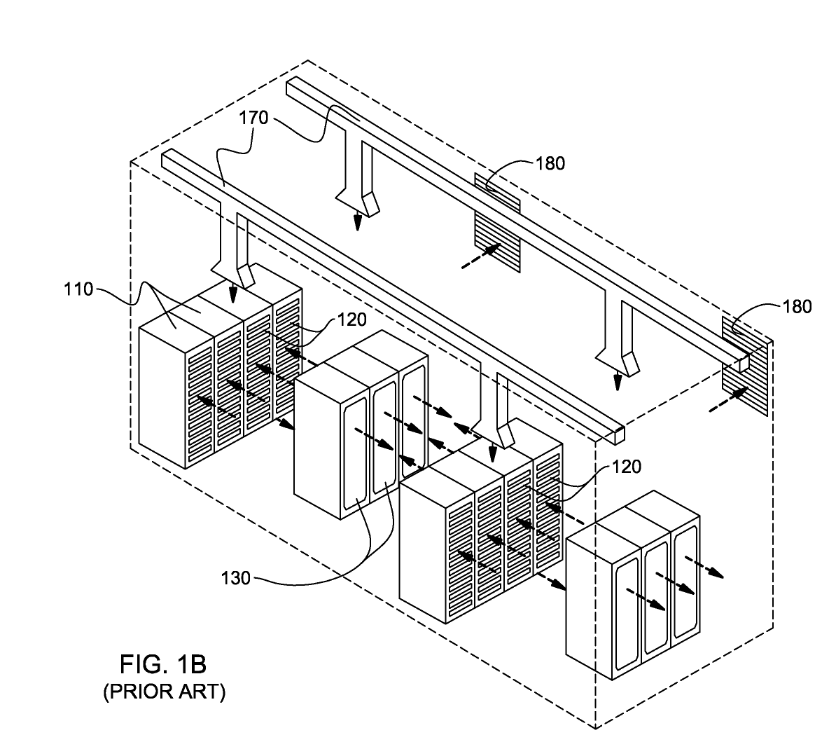

FIG. 1A depicts a raised floor layout of an air cooled data center 100 typical in the prior art, wherein multiple electronics racks 110 are disposed in one or more rows. A data center such as depicted in FIG. 1A may house several hundred, or even several thousand microprocessors. In the arrangement illustrated, chilled air enters the computer room via perforated floor tiles 160 from a supply air plenum 145 defined between the raised floor 140 and a base or sub-floor 165 of the room. Cooled air is taken in through louvered covers at air inlet sides 120 of the electronics racks and expelled through the back (i.e., air outlet sides 130) of the electronics racks. Each electronics rack 110 may have one or more air moving devices (e.g., fans or blowers) to provide forced inlet-to-outlet airflow to cool the electronic components within the drawer(s) of the rack. The supply air plenum 145 provides conditioned and cooled air to the air-inlet sides of the electronics racks via perforated floor tiles 160 disposed in a “cold” aisle of the computer installation. The conditioned and cooled air is supplied to plenum 145 by one or more air conditioning units 150, also disposed within the data center 100. Room air is taken into each air conditioning unit 150 near an upper portion thereof. This room air comprises in part exhausted air from the “hot” aisles of the computer installation defined by opposing air outlet sides 130 of the electronics racks 110.

FIG. 1B depicts an alternate data center configuration wherein multiple electronics racks 110 disposed in rows are cooled via conditioned and cooled air entering the room from overhead ducts and diffusers 170. Air exits the room via vents 180 that may be placed at different locations within the room. The ducts and diffusers 170 are disposed to align to the cold aisle of the multiple rows and provide cooled air to the air inlet sides 120 of the electronics racks. Air moving devices within the racks move the cooled air through the racks from inlet side to outlet side to cool the heat generating components therein. Heated air is again exhausted at the hot aisles of the racks through the air outlet sides 130 of electronics racks 110. In one embodiment, returns 180 can be aligned to the hot aisles defined by the opposing air exhaust sides 130 of the electronics racks.

Due to the ever increasing airflow requirements through electronics racks, and limits of air distribution within the typical data center installation, re-circulation problems within the room may occur. This is shown in FIG. 2 for a raised floor layout, wherein hot air re-circulation 200 occurs from the air outlet sides 130 of the electronics racks 110 back to the cold air aisle defined by the opposing air inlet sides 120 of the electronics rack. This re-circulation can occur because the conditioned air supplied through tiles 160 is typically only a fraction of the airflow rate forced through the electronics racks by the air moving devices disposed therein. This can be due, for example, to limitations on the tile sizes (or diffuser flow rates). The remaining fraction of the supply of inlet side air is often made up by ambient room air through re-circulation 200. This recirculating flow is often very complex in nature, and can lead to significantly higher rack unit inlet temperatures than desired.

The re-circulation of hot exhaust air from the hot aisle of the computer room installation to the cold aisle can be detrimental to the performance and reliability of the computer system(s) or electronic system(s) within the racks. Data center equipment is typically designed to operate with rack air inlet temperatures in the 18-35° C. range. For a raised floor layout such as depicted in FIG. 1A, however, temperatures can range from 15-20° C. at the lower portion of the rack, close to the cooled air input floor vents, to as much as 45-50° C. at the upper portion of the electronics rack, where the hot air can form a self-sustaining re-circulation loop. Since the allowable rack heat load is limited by the rack inlet air temperature at the “hot” part, this temperature distribution correlates to an inefficient utilization of available chilled air. Also, computer installation equipment almost always represents a high capital investment to the customer. Thus, it is of significant importance, from a product reliability and performance view point, and from a customer satisfaction and business perspective, to limit the temperature of the inlet air to the rack unit to be substantially uniform. The efficient cooling of such computer and electronic systems, and the amelioration of localized hot air inlet temperatures to one or more rack units due to re-circulation of air currents, are addressed by the apparatuses and methods disclosed herein, as is reducing acoustic noise within the data center.

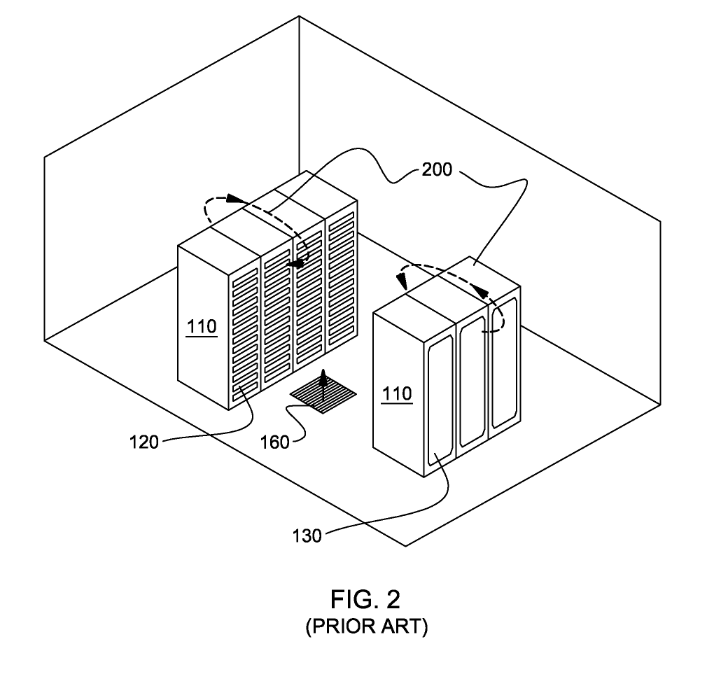

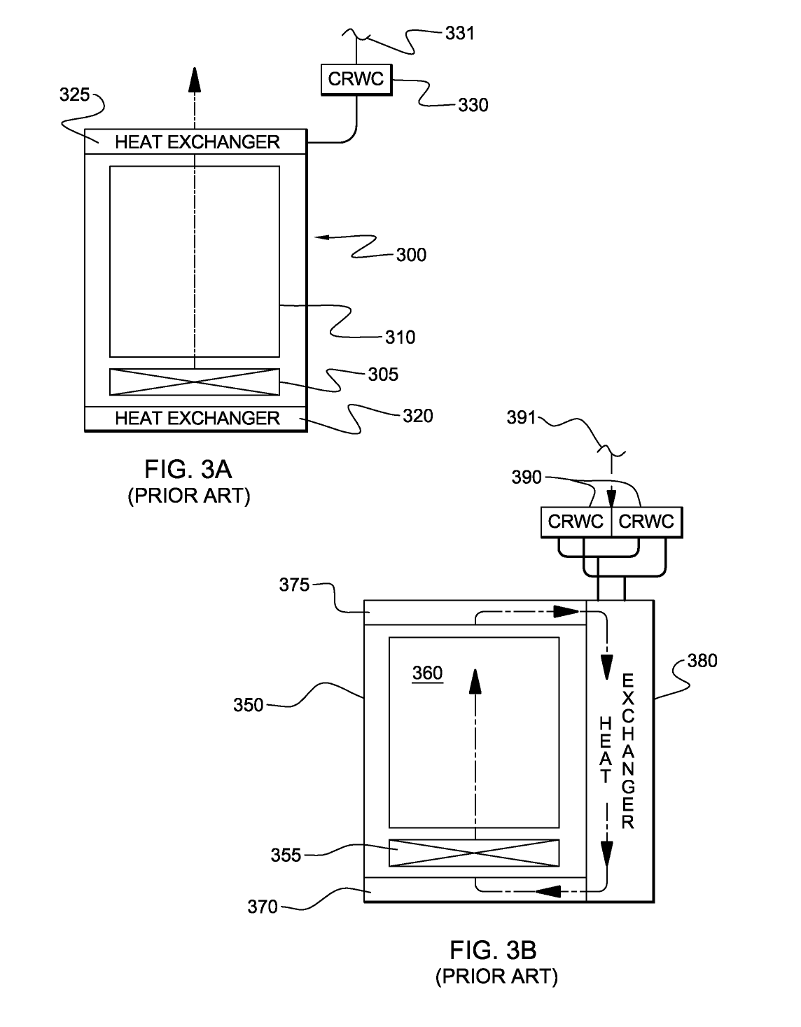

FIGS. 3A and 3B depict prior rack level water cooled solutions which utilize chilled facility water to remove heat from the computer installation room, thereby transferring the cooling burden from the air-conditioning units to the building chilled water coolers. The embodiment of FIG. 3A is described in detail in commonly assigned U.S. Pat. No. 6,819,563, while the embodiment of FIG. 3B is described in detail in commonly assigned U.S. Pat. No. 6,775,137, both of which are incorporated herein by reference in their entirety. Briefly summarized, both embodiments utilize a computer room water conditioning unit 330 (FIG. 3A), 390 (FIG. 3B) (fed with facility chilled water 331 (FIG. 3A), 391 (FIG. 3B)), which circulates chilled coolant through one or more heat exchangers coupled to individual electronics racks 300, 350 within the computer room.

In the embodiment of FIG. 3A, electronics rack 300 has an inlet heat exchanger 320 and/or an outlet heat exchanger 325 attached to the rack. Airflow across one or more electronics drawers 310 is forced via one or more air moving devices 305. Each heat exchanger 320, 325 covers the complete airflow paths from front to back, with the air intake being chilled by heat exchanger 320, and the heated exhaust chilled by heat exchanger 325. Thus, the inlet-to-outlet airflow paths through the rack unit each pass through the same sequence of heat exchangers.

In FIG. 3B, rack unit 350 again includes one or more air moving devices 355 for moving airflow from an air inlet side to an air outlet side across one or more drawer units 360 containing the heat generating components. In this embodiment, a front cover 370 attached to the rack covers the air inlet side, a back cover 375 attached to the rack covers the air outlet side thereof, and a side car attached to the rack includes a heat exchanger 380 for cooling of the air circulating through the rack unit. Further, in this embodiment, multiple computer room water conditioning (CRWC) units 390 receive building or facility chilled water 391, which is then used to cool coolant circulating through heat exchanger 380. The rack unit in this example is assumed to comprise a substantially enclosed housing wherein the same air circulates through the housing and passes across the heat exchanger 380.

One drawback to the rack level water cooled solutions depicted in FIGS. 3A & 3B is the assembly required to attach the front heat exchanger, back heat exchanger, front door, back door and/or side car (depending on the configuration) to the electronics rack either by the manufacturer or the data center operator. The solutions depicted in FIGS. 3A & 3B need to be customized to a particular manufacturer's electronics rack. Further, as heat loads continue to increase to 100 kW and beyond, the air-to-liquid heat exchangers required to cool the racks will be very large. Therefore, it may be impractical to have such large and heavy structures attached to the electronics racks themselves.

Advantageously, the invention disclosed herein solves, in one aspect, the problems noted above by providing a modular docking station separate and freestanding from the electronics rack, which includes an air-to-liquid heat exchange assembly disposed therein, and facilitates defining a closed loop airflow path passing through the electronics rack and heat exchange assembly. When operational, hot air exiting the electronics rack within the sealed enclosure of the docking station passes through the heat exchange assembly and is cooled before returning to an air inlet side of the electronics rack. Containment of the airflow within the docking station reduces the level of acoustic emissions to the outside data center room. Further, rejection of substantially 100% of the electronics rack heat load via the liquid-to-air heat exchange assembly of the docking station dramatically reduces the number of noisy, less efficient computer room air-conditioning units required within the data center.

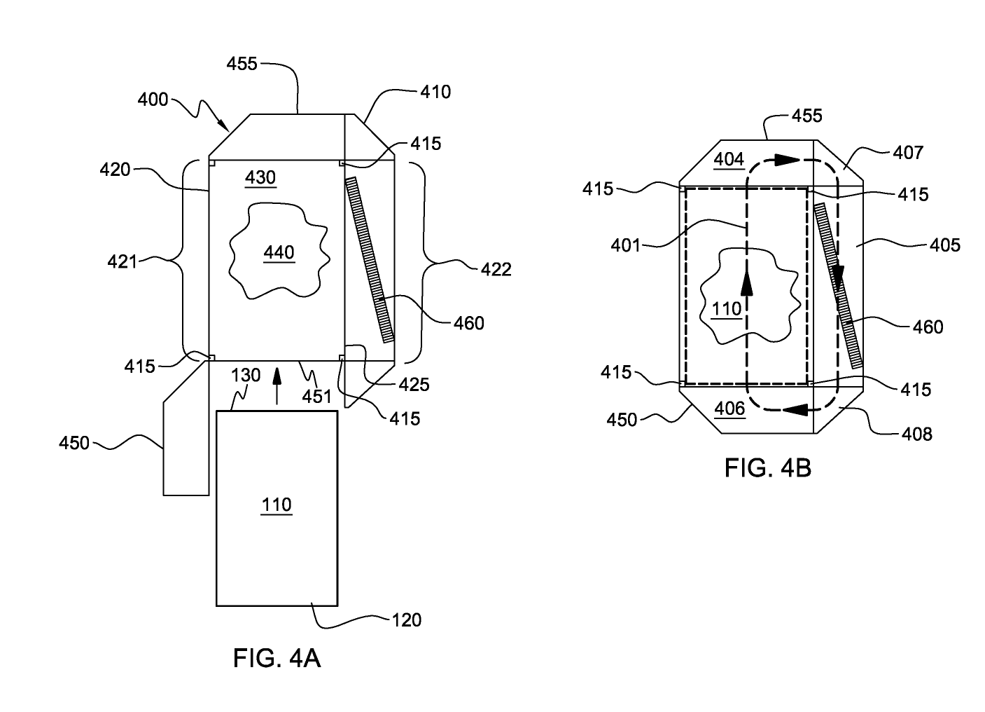

One embodiment of a docking station 400 in accordance with the invention disclosed herein is presented in FIGS. 4A & 4B. In this embodiment, docking station 400 comprises an enclosure 410 with at least one outer wall 420 and a top cover 430 connected to the at least one outer wall 420. A central opening 440 is defined between a portion 421 of outer wall 420 and an inner side wall 425 disposed in spaced opposing relation to portion 421 of outer wall 420. These opposing walls 421, 425 are spaced to receive electronics rack 110 there between. Electronics rack 110 again comprises, for example, one or more heat generating components disposed therein requiring cooling, and includes an air inlet side 120 and an air outlet side 130, with the air inlet and air outlet sides respectively enabling ingress and egress of air through electronics rack 110, propelled, for example, via one or more fans (not shown) disposed within the rack unit.

Electronics rack 110 is slid or rolled into position within central opening 440 through an access opening 451 in the at least one wall 420 exposed, for example, by pivoting open a hinged front door 450. Similarly, a back door 455 also hingedly mounts within docking station 400 allows access to, for example, the air outlet side of electronics rack 110 once in operative position within the docking station. One or more gaskets 415 may be disposed on an inner surface of wall portion 421 and on inner side wall 425 as illustrated in FIG. 4A. These gaskets 415, disposed in one embodiment at the four corners of electronics rack 110 when operatively positioned within central opening 440, engageably compress against electronics rack 110 to seal the space between electronics rack 110 and portion 421 of outer wall 420 and the space between electronics rack 110 and inner side wall 425 as illustrated in FIG. 4B.

Advantageously, outer wall 420 and cover 430 of enclosure 410 encircle and seal electronics rack 110 within docking station 400 once the rack is in operative position within central opening 440 and front cover 450 is closed, as illustrated in FIG. 4B. This allows a closed loop airflow path 401 to be established within the docking station passing through electronics rack 110, with airflow circulating from air inlet side 120 of electronics rack 110 to air outlet side 130 (propelled, for example, by the one or more fans disposed within electronics rack 110). The closed loop airflow path 401 passes through an air-to-liquid heat exchange assembly 460 disposed in the embodiment of FIGS. 4A & 4B in a side air return pathway 405 defined between a portion 422 of outer wall 420 and inner side wall 425, spaced in opposing relation therewith as illustrated. In addition to side air return pathway 405, a rear door air return pathway 404, and a front door air return pathway 406 are provided by appropriately configuring rear door 455 and front door 450, respectively, as illustrated. Interconnecting corner air flow pathways 407, 408 couple rear door air flow pathway 404, side air return pathway 405 and front door air return pathway 406 to allow air to circulate in the closed loop airflow path 401 of the docking station.

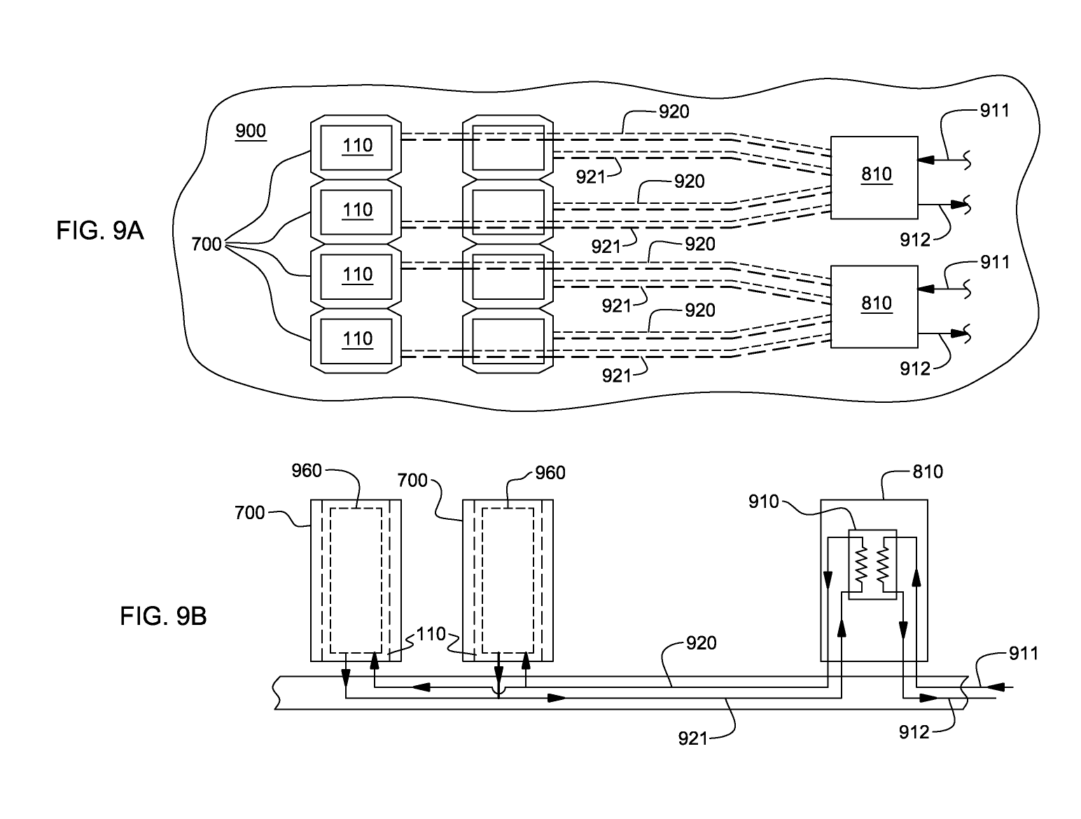

In one embodiment, closed loop airflow path 401 is established within the enclosure for substantially the height of the electronics rack, for example, from a lower most electronics drawer of the electronics rack to an upper most electronics drawer of the electronics rack. Similarly, the air-to-liquid heat exchange assembly 460 is configured to extend vertically within the side air return pathway 405 for substantially the height of electronics rack 110 to ensure maximum cooling of circulating air within the closed loop air return path. In one embodiment, coolant supply and return lines (see FIG. 9B) extend below a raised floor of the data center room and project into the docking station below, for example, air-to-liquid heat exchange assembly 460. The supply and return lines respectively couple to an inlet and an outlet of the heat exchange assembly. In one implementation, quick disconnect couplings may be employed at the interface between the coolant supply line and heat exchange assembly inlet, and between the coolant return line and heat exchange assembly outlet.

Advantageously, with the electronics rack positioned within the docking station and the access doors closed to seal the electronics rack therein, leakage of air and acoustic noise into the data center room is minimized, or substantially prevented.

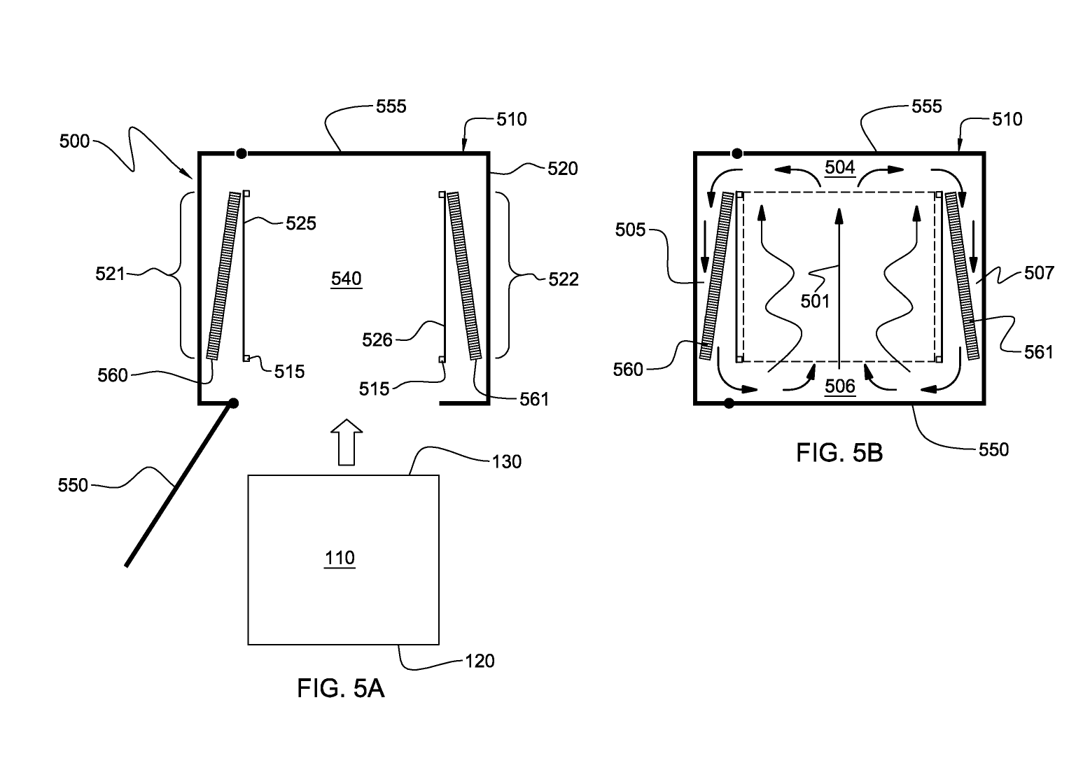

FIGS. 5A & 5B depict an alternate embodiment of a docking station 500 with a dual air-to-liquid heat exchange assembly configuration and a bifurcated closed loop airflow path. Advantageously, this implementation can provide more uniformly distributed airflow to the air inlet side of the electronics rack.

Docking station 500 again includes an enclosure 510 configured to receive and encircle electronics rack 110. The electronics rack is received into a central opening 540 defined by spaced, opposing inner side walls, 525, 526, which are also respectively in opposing relation to portions 521, 522 of at least one outer wall 520 defining enclosure 510, along with a top cover disposed over the at least one outer wall. Gaskets 515, disposed in one embodiment at the four corners of electronics rack 110 when operatively positioned within central opening 540, engagably compress against electronics rack 110 to seal the space between electronics rack 110 and the inner side walls, as illustrated in FIG. 5B.

Together, the at least one outer wall and cover, encircle and seal electronics rack 110 within the docking station when in operative position within central opening 540 thereof. As shown in FIG. 5B, enclosure 510 is sized to define a bifurcated closed loop airflow path 501 when the electronics rack is operatively disposed therein. This bifurcated closed loop airflow path passes through a back door air return pathway 504 (defined between the air outlet side 130 of electronics rack 110 and an inner surface of a back access door 555), side air return pathways 505, 507 and a front air return pathway 506 (defined between a front access door 550 and air inlet side 120 of electronics rack 110).

By dividing the closed loop air flow path into a bifurcated flow as illustrated in FIG. 5B, a more uniform distribution of airflow to the air inlet side of electronics rack 110 is achieved. Air-to-liquid heat exchange assemblies 560, 561 are disposed, in this embodiment, within side air return pathways 505, 507, respectively. In one embodiment, the side air return pathways 505, 507, and the heat exchange assemblies 560, 561 both extend for substantially the height of the electronics rack, for example, from below a lower most electronics drawer of the rack to above an upper most electronics drawer of the rack. A maximum cooling of circulating air within the bifurcated closed loop airflow path 501 is ensured by sizing assemblies 560, 561 within pathways 505, 507 to guarantee that circulating air passes through one of the heat exchange assemblies before returning to the air inlet side of the rack unit. Coolant supply and return lines may again extend, for example, from below a raised floor of the data center room and project into the docking station below the respective air-to-liquid heat exchange assemblies 560, 561. Quick disconnect couplings may be employed at the interface between the coolant supply and return lines and the heat exchange assemblies' inlets and outlets.

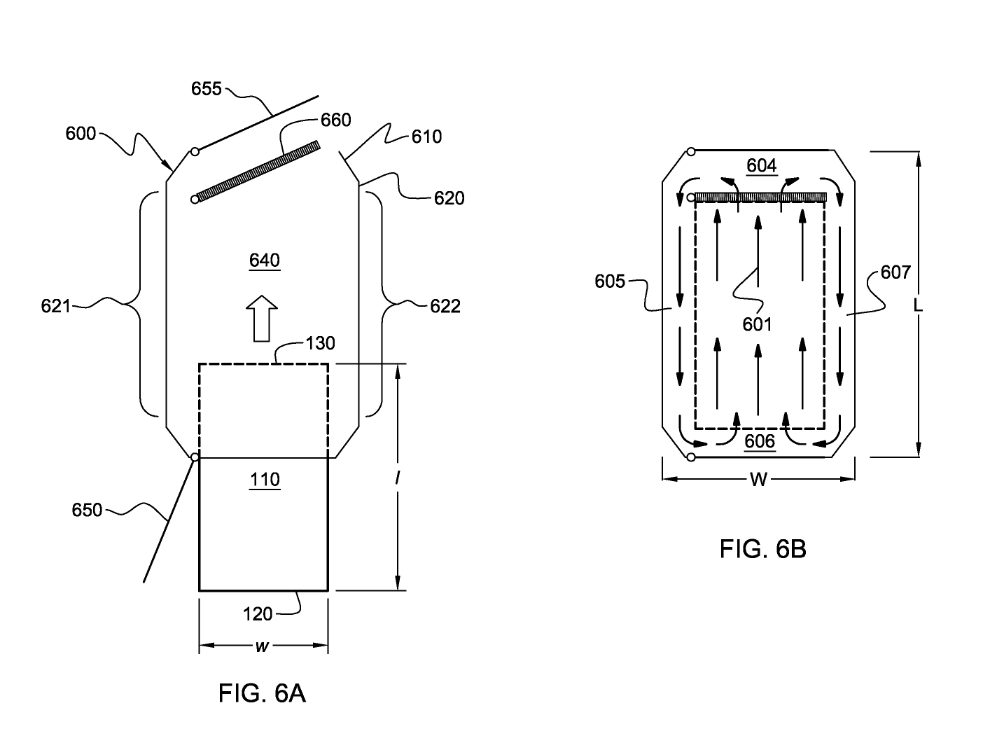

FIGS. 6A & 6B depict a further embodiment of a docking station 600 incorporating a bifurcated closed loop airflow path. In this embodiment, an air-to-liquid heat exchange assembly 660 is pivotally connected within the docking station to be disposed at the air outlet side of electronics rack 110 when the rack is operatively positioned within the docking station.

Docking station 600 includes an enclosure 610 configured to receive electronics rack 110 within a central opening 640 thereof. In one embodiment, central opening 640 is defined by spaced, opposing inner sidewalls (not shown). Alternatively, the spaced, inner side walls may be omitted in an implementation where electronics rack 110 itself comprises substantially enclosed sides transverse to the air inlet side 120 and air outlet side 130 of the electronics rack. In such an implementation, air-to-liquid heat exchange assembly 660 could be pivotally connected to a post disposed within the docking station. If present, the spaced, inner side walls are respectively in opposing relation to portions 621, 622 of at least one outer wall 620 of enclosure 610. Enclosure 610 further includes a cover disposed over the at least one outer wall. Together, the at least one outer wall and cover define enclosure 610 which encircles and encloses electronics rack 110 therein when the rack is operatively positioned within central opening 640 thereof.

In the embodiment illustrated, a front access door 650 hingedly connects to enclosure 610 to allow access through a front access opening to central opening 640. Similarly, a back access door 655 is hingedly connected to enclosure 610 to allow access, for example, to either the air-to-liquid heat exchange assembly 660 or the air outlet side 130 of electronics rack 110 when positioned operatively therein. As noted, the air-to-liquid heat exchange assembly 660 is also pivotally connected within the docking station to allow access to the air outlet side of electronics rack 110. The heat exchange assembly 660 is sized, in one embodiment, so that all air egressing from electronics rack 110, when operatively positioned within the docking station, passes through the air-to-liquid heat exchange assembly for cooling thereof before returning to the air inlet side of the electronics rack.

The bifurcated closed loop airflow path 601 is illustrated in FIG. 6B. This airflow path is established by sizing enclosure 610 so that dual air return pathways are established within the enclosure when the electronics rack is operatively positioned therein as shown. These dual air return pathways pass through a back air return pathway 604, one of two side air return pathways 605, 607 and a front air return pathway 606. As illustrated, back air return pathway 604 and front air return pathway 606 are defined by appropriately sizing enclosure 610 to extend beyond electronics rack 110 when the rack is operatively positioned within the central opening thereof. Similarly, side air return pathways 605, 607 are defined by spacing portions 621, 622 of outer side wall 620 an appropriate distance from the sides of the rack, or alternatively, from the optional inner side walls (not shown). In one specific example, the width ‘w’ and length ‘l’ of electronics rack 110 may be 24 inches and 40 inches respectively, while the width ‘W’ and length ‘L’ of enclosure 610 may be 44 inches and 56 inches, respectively.

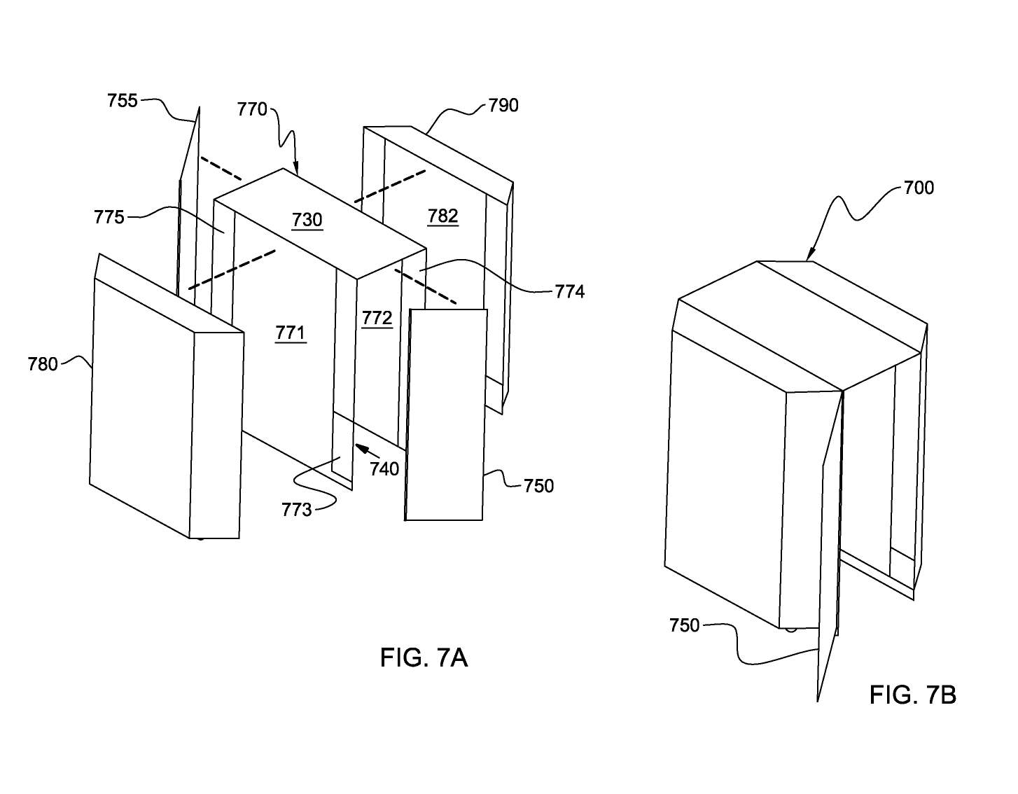

FIGS. 7A & 7B depict an isometric view of one embodiment of a docking station 700 comprising a central structure 770 and two side structures 780, 790. As shown, central structure 770 is sized to receive an electronics rack within a central opening 740 defined therein between spaced, opposing inner side walls 771, 772, and a top cover 730. The spaced, opposing inner side walls include front inner side wall openings 773, 774 and back inner side wall openings, with only back inner side wall opening 775 in inner side wall 771 being illustrated in the isometric view. Inner side wall 772 would contain a similar back inner side wall opening.

Side structures 780 & 790 are designed to be affixed to and are sized to cover a respective one of the first and second inner side walls 771, 772 of the central structure 770. Each side structure 780, 790 comprises an outer wall spaced from a respective one of the first and second inner wall (782 for structure 790) to facilitate defining a first side air return pathway and a second side air return pathway therethrough. A hingedly connected front access door 750 and a hingedly connected back access door 755 are also attached to central structure 770 to allow access to the central opening for positioning the rack therein, and access to the air inlet and air outlet sides of the rack once operatively positioned within the docking station.

In the docking station embodiment of FIGS. 7A & 7B, a bifurcated closed loop airflow path is established within the enclosure, with circulating air passing through the air inlet and air outlet sides of the electronics rack, the back inner side openings in the inner side walls of the central structure, the side air return pathways through the side structures and the front inner side wall openings. As in the previously described embodiments, the inner side walls of the central structure could each comprise one or more gaskets designed to compressibly engage opposing sides of the electronics rack when the rack is disposed in operative position within the central opening of the enclosure to provide airtight seals between the central structure and the sides of the electronics rack and thereby facilitate establishing the bifurcated closed loop airflow path within the docking station.

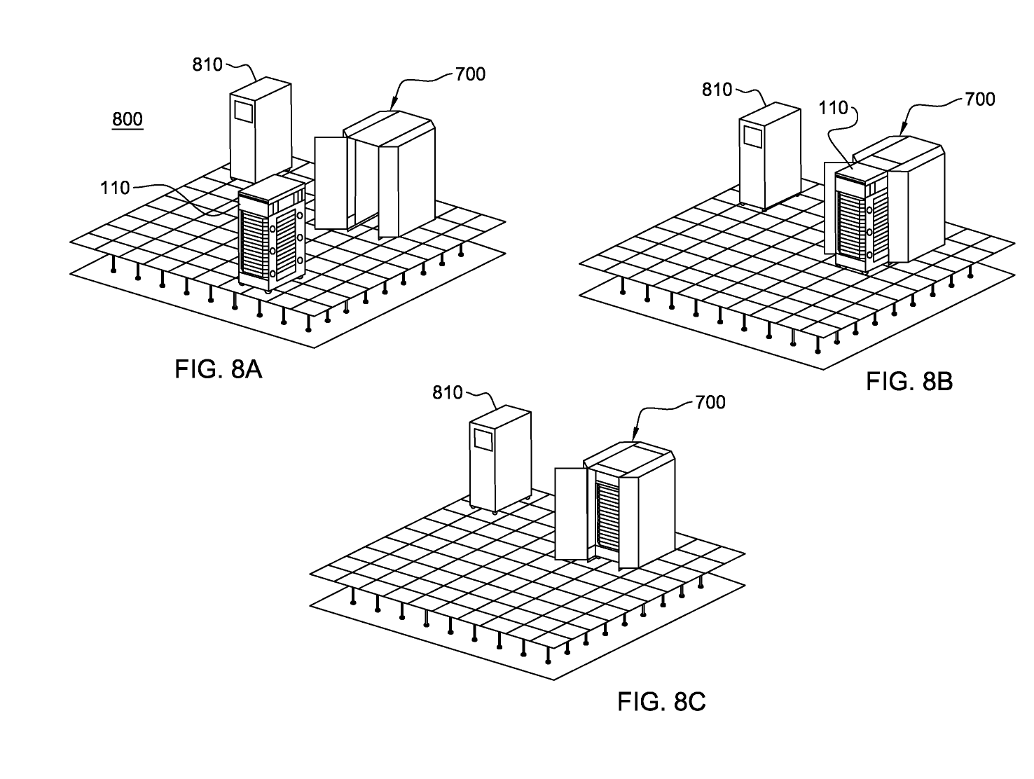

FIGS. 8A-8C illustrate one embodiment of a data center 800 employing one or more docking stations 700 such as described above in connection with FIGS. 7A & 7B. The data center depicted is again a raised floor data center wherein an electronics rack 110 is shown being rolled into position through a front access opening in the docking station. The data center 800 further includes a coolant distribution unit 810 which may supply coolant to one or multiple docking stations within the data center, and more particularly, to the one or more air-to-liquid heat exchange assemblies of the docking station(s). In one embodiment, docking station 700 is bolted to the floor of the data center, and is thus separate and free-standing from the electronics rack to be cooled.

FIGS. 9A & 9B illustrate in greater detail one embodiment of data center 900 wherein a plurality of docking stations 700 are aligned in rows, each with a respective electronics rack 110 disposed in operative position therein. In this embodiment, multiple coolant distribution units 810 supply coolant to the docking stations. As shown in FIG. 9B, in one embodiment, the coolant distribution unit includes a liquid-to-liquid heat exchange assembly 910 wherein facility chilled water passing through facility water lines 911, 912 cools system coolant passing through supply and return lines 920, 921 for facilitating cooling of the air circulating within the individual docking stations via the one or more heat exchange assemblies 960 disposed therein. The coolant distribution units may supply conditioned, temperature controlled water or other suitable cooling liquid to the air-to-liquid heat exchange assemblies within the docking stations. One coolant distribution unit may supply multiple docking stations. In one embodiment, each coolant distribution unit 810 includes a power/control element, a reservoir/expansion tank, a liquid-to-liquid heat exchange assembly 910, a pump (which may be accompanied by a redundant second pump), facility water (or site or customer service water or coolant), inlet and outlet supply pipes, a supply manifold directing coolant to the docking stations via appropriate couplings, and a return manifold directing water from the docking stations via appropriate couplings. In the embodiment illustrated in FIGS. 9A & 9B, each coolant distribution unit 810 supplies system coolant to the heat exchange assemblies within four docking stations.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. A docking station for facilitating cooling of an electronics rack, the docking station comprising:
an enclosure comprising at least one wall, a cover coupled to the at least one wall, and a central opening sized to receive an electronics rack therein through an access opening in the at least one wall, the enclosure being separate and freestanding from the electronics rack, and the electronics rack comprising at least one electronics drawer and an air inlet side and an air outlet side, the air inlet and air outlet sides of the electronics rack respectively enabling ingress and egress of air, and wherein when the electronics rack is operatively positioned within the central opening, the enclosure surrounds the electronics rack and facilitates establishing a closed loop airflow path therein passing through the air inlet and air outlet sides of the electronics rack and through at least one air return pathway of the enclosure; and
at least one air-to-liquid heat exchange assembly disposed within the at least one air return pathway of the enclosure for cooling air circulating through the closed loop airflow path.

2. The docking station of claim 1, wherein an outer side wall of the at least one wall of the enclosure is spaced from and partially in opposing relation with a side of the electronics rack when the electronics rack is operatively positioned within the central opening of the enclosure, and the at least one air return pathway of the enclosure comprises at least one side air return pathway disposed between the outer side wall of the enclosure and side of the electronics rack, and wherein the enclosure forms a substantially airtight seal about the electronics rack when the electronics rack is operatively positioned within the central opening of the enclosure.

3. The docking station of claim 2, wherein the access opening is a front access opening, and the at least one wall of the enclosure further comprises a back access opening and the enclosure further comprises a front access door sized to cover the front access opening and a back access door sized to cover the back access opening, wherein the front access opening and door, and back access opening and door, facilitate positioning of the electronics rack within the central opening of the enclosure and facilitate access to the air inlet and air outlet sides of the electronics rack once operatively positioned within the enclosure.

4. The docking station of claim 3, wherein the enclosure further comprises an inner side wall, and wherein the outer side wall and the inner side wall are at least partially in spaced opposing relation and define a side air return pathway of the at least one side air return pathway, wherein the inner side wall of the enclosure is disposed adjacent to the side of the electronics rack when the rack is operatively positioned within the central opening of the enclosure, and wherein the at least one air-to-liquid heat exchange assembly is disposed within the side air return pathway defined between the outer wall and the inner wall, and is sized to cool air from the air outlet side of the electronics rack prior to return thereof to the air inlet side of the electronics rack.

5. The docking station of claim 3, wherein the enclosure is configured with a first outer side wall in spaced opposing relation to a first side of the electronics rack and a second outer side wall in spaced opposing relation to a second side of the electronics rack when the electronics rack is operatively positioned within the central opening of the enclosure, wherein the first side and second side of the electronics rack are opposite sides of the electronics rack which extend transverse to the air inlet side and air outlet side thereof, and wherein the first and second outer side walls of the enclosure in spaced opposing relation to the first and second sides of the electronics rack respectively define first and second side air return pathways extending along the first and second opposing sides of the electronics rack, and wherein the closed loop airflow path is bifurcated and passes through the first and second side air return pathways, with airflow through the electronics rack bifurcating at the air outlet side thereof and recirculating through one of the first and second air return pathways defined on opposite sides of the electronics rack, and wherein the at least one air-to-liquid heat exchange assembly comprises a back air-to-liquid heat exchange assembly pivotally connected within the enclosure to allow access to the air outlet side of the electronics rack and sized to cover the air outlet side of the electronics rack to cool, when operational, air egressing from the electronics rack.

6. The docking station of claim 3, wherein the enclosure comprises first and second inner side walls and first and second side air return pathways, each side air return pathway being defined between a respective outer side wall of the enclosure and one of the first and second inner side walls, the first and second inner side walls extending along opposing sides of the electronics rack when the electronics rack is operatively positioned within the central opening of the enclosure, and wherein the closed loop airflow path is bifurcated and passes through the first and second side air return pathways, with air flow through the electronics rack bifurcating at the air outlet side thereof and returning to the air inlet side of the electronics rack via the first and second side air return pathways.

7. The docking station of claim 6, wherein the docking station comprises a first air-to-liquid heat exchange assembly disposed within the first side air return pathway and a second air-to-liquid heat exchange assembly disposed within the second side air return pathway and wherein the first and second air-to-liquid heat exchange assemblies are sized to cool air egressing from the air outlet side of the electronics rack before returning to the air inlet side of the electronics rack.

8. The docking station of claim 1, wherein the enclosure comprises a central structure, a first side structure and a second side structure, the central structure being sized to receive the electronics rack and comprising first and second inner side walls spaced in opposing relation, the first and second inner side walls of the central structure including front inner side wall openings and back inner side openings, and the first and second side structures being affixed to and sized to cover the first and second inner side walls of the central structure and each comprising an outer wall which partially defines a respective one of a first side air return pathway and a second side air return pathway, wherein the closed loop air flow path is bifurcated and air egressing from the air outlet side of the electronics rack returns to the air inlet side of the of the electronics rack through the back inner side wall openings, the first and second side air return pathways, and the front inner sidewall openings.

9. The docking station of claim 8, wherein the first and second inner side walls of the central structure each comprise at least one gasket for compressibly engaging a side of the electronics rack when the electronics rack is operatively positioned within the central opening of the enclosure, the at least one gasket providing an airtight seal between the central structure and at least one side of the electronics rack, thereby facilitating establishing of the bifurcated closed loop airflow path passing through the first and second air return pathways.

10. A data center comprising:
at least one electronics rack, each electronics rack comprising an air inlet side and an air outlet side, the air inlet and air outlet sides respectively enabling ingress and egress of air through the electronics rack; and
at least one docking station, each docking station comprising:
an enclosure comprising at least one wall, a cover coupled to the at least one wall and a central opening sized to receive a respective electronics rack therein through an access opening in the at least one wall, the enclosure being separate and freestanding from the electronics rack, wherein the enclosure surrounds the electronics rack and facilitates establishing a closed loop airflow path therein passing through the air inlet and air outlet sides of the electronics rack and through at least one air return pathway of the enclosure; and
at least one air-to-liquid heat exchange assembly disposed within the at least one air return pathway of the enclosure for cooling air circulating through the closed loop airflow path.

11. The data center of claim 10, wherein an outer side wall of the at least one wall of the enclosure of each docking station is spaced from and partially in opposing relation with a side of the respective electronics rack when the electronics rack is operatively positioned within the central opening of the enclosure, and the at least one air return pathway of the enclosure comprises at least one side air return pathway disposed between the outer side wall and a side of the electronics rack, and wherein the enclosure forms a substantially airtight seal about the electronics rack when the electronics rack is operatively positioned within the central opening of the enclosure.

12. The data center of claim 11, wherein the access opening is a front access opening in the enclosure, and the at least one wall of the enclosure further comprises a back access opening, and the enclosure of each docking station further comprises a front access door sized to cover the front access opening and a back access door sized to cover the back access opening, wherein the front access opening and door, and the back access opening and door, facilitate positioning of the electronics rack within the central opening of the enclosure and facilitate access to the air inlet and air outlet sides of the electronics rack when operatively positioned within the enclosure.

13. The data center of claim 12, wherein the enclosure of each docking station further comprises an inner side wall, and wherein the outer side wall and the inner side wall are at least partially in spaced opposing relation and define a side air return pathway of the at least one side air return pathway, wherein the inner side wall of the enclosure is disposed adjacent to the side of the electronics rack when the electronics rack is operatively positioned within the central opening of the enclosure, and wherein the at least one air-to-liquid heat exchange assembly is disposed within the side air return pathway defined between the outer side wall and the inner side wall, and is sized to cool air from the air outlet side of the electronics rack prior to return thereof to the air inlet side of the electronics rack.

14. The data center of claim 12, wherein the enclosure is configured with a first outer side wall in spaced opposing relation to a first side of the electronics rack and a second outer side wall in spaced opposing relation to a second side of the electronics rack when the electronics rack is operatively positioned within the central opening of the enclosure, wherein the first side and second side of the electronics rack are opposite sides of the electronics rack which extend transverse to the air inlet side and air outlet side thereof, and wherein the first and second outer side walls of the enclosure in spaced opposing relation to the first and second sides of the electronics rack respectively define first and second return pathways extending along the first and second opposing sides of the electronics rack, and wherein the closed loop airflow path is bifurcated and passes through the first and second side air return pathways, with air flow through the electronics rack bifurcating at the air outlet side thereof and recirculating through one of the first and second air return pathways disposed on opposite sides of the electronics rack, and wherein the at least one air-to-liquid heat exchange assembly comprises a back air-to-liquid heat exchange assembly pivotally connected within the enclosure to allow access to the air outlet side of the electronics rack and sized to cover the air outlet side of the electronics rack to cool, when operational, air egressing from the electronics rack.

15. The data center of claim 12, wherein the enclosure comprises first and second inner side walls and first and second side air return pathways, each side air return pathway being defined between a respective outer side wall of the enclosure and one of the first and second inner side walls, the first and second inner side walls extending along opposing sides of the electronics rack when the electronics rack is operatively positioned within the central opening of the enclosure, and wherein the closed loop airflow path is bifurcated and passes through the first and second side air return pathways, with air flow through the electronics rack bifurcating at the air outlet side thereof and returning to the air inlet side of the electronics rack through the first and second side air return pathways.

16. The data center of claim 15, wherein each docking station comprises a first air-to-liquid heat exchange assembly disposed within the first side air return pathway and a second air-to-liquid heat exchange assembly disposed within the second side air return pathway, and wherein the first and second air-to-liquid heat exchange assemblies are sized to cool air egressing from the air outlet side of the electronics rack before returning to the air inlet side of the electronics rack.

17. The data center of claim 10, wherein the data center comprises a plurality of electronics racks and a plurality of docking stations, each docking station having a respective electronics rack of the plurality of electronics racks disposed in operative position within the central opening of the enclosure thereof, and wherein the plurality of docking stations are aligned in at least one row within the data center, and wherein the data center further comprises at least one coolant distribution unit providing liquid coolant to the air-to-liquid heat exchange assemblies of the plurality of docking stations.

18. The data center of claim 10, wherein the at least one air-to-liquid heat exchange assembly within each docking station is configured and sized to fit within the at least one air return pathway of the enclosure so that air circulating through the closed loop airflow path necessarily passes therethrough.

19. The data center of claim 18, wherein the at least one air-to-liquid heat exchange assembly of each docking station is sized and configured to extend vertically within the enclosure a distance at least equal to a height of an air outlet opening in the air outlet side of the respective electronics rack.

20. A method of cooling an electronics rack, the method comprising:
providing a docking station for cooling an electronics rack, the docking station comprising:
an enclosure comprising at least one wall, a cover coupled to the at least one wall, and a central opening sized to receive the electronics rack therein through an access opening in the at least one wall, the enclosure being separate and freestanding from the electronics rack, and the electronics rack comprising an air inlet side and an air outlet side, the air inlet and air outlet sides respectively enabling ingress and egress of air; and
at least one air-to-liquid heat exchange assembly disposed within at least one air return pathway of the enclosure for cooling circulating air passing therethrough;
disposing the electronics rack within the central opening and sealing the electronics rack within the enclosure;
establishing airflow through the electronics rack employing at least one air moving device, wherein the establishing results in a closed loop airflow path being established within the enclosure, the closed loop airflow path passing through the air inlet and air outlet sides of the electronics rack and through the at least one air return pathway of the enclosure; and
employing the at least one air-to-liquid heat exchange assembly to cool air circulating within the enclosure through the closed loop airflow path.
